(19) United States
(12) Patent Application Publication
(10) Pub. No.: US 2025/0350095 A1
(43) Pub. Date: Nov. 13, 2025

(54) VCSEL DEVICE WITH ASYMMETRIC OXIDE APERTURE AND METHOD OF MAKING SAME

(71) Applicant: Applied Optoelectronics, Inc., Sugar Land, TX (US)

(72) Inventors: Dapeng XU, Houston, TX (US); Klaus Alexander ANSELM, Sugar Land, TX (US)

(21) Appl. No.: 19/199,808

(22) Filed: May 6, 2025

Related U.S. Application Data
(60) Provisional application No. 63/644,154, filed on May 8, 2024.

(51) Int. Cl. H01S 5/183

(52) U.S. Cl. CPC H01S 5/18394; H01S 5/18361

(57) ABSTRACT

In a VCSEL device with an asymmetric oxide aperture, the asymmetric oxide aperture has a low symmetry shape or pattern with an order of rotation symmetry of zero. An oxide aperture having such a low symmetry pattern breaks the symmetry to eliminate degenerate modes and instability of polarization, which reduces relative intensity noise (RIN) and root-mean-square (RMS) spectra width. In one embodiment, the low symmetry pattern of the asymmetric oxide aperture may be a partial circle, such as a semi-circle or quarter circle, and the arc angle θ of the partial circle may be reduced to increase the OA control limit.

### CROSS-REFERENCE TO RELATED APPLICATIONS

The present application claims the benefit of U.S. Provisional Patent Application Ser. No. 63/644,154, filed on May 8, 2024, which is incorporated herein by reference.

### TECHNICAL FIELD

The present disclosure relates to semiconductor lasers and more particularly, to a vertical cavity surface emitting laser (VCSEL) device with an asymmetric oxide aperture.

### BACKGROUND INFORMATION

A vertical cavity surface emitting laser (VCSEL) is a type of semiconductor laser diode with laser beam emission from the top surface. VCSELs may be used in various applications, such as 400 G/800 G active optical cables (AOCs). In one type of VCSEL, oxide may be used to restrict or confine the current in the VCSEL by oxidizing the material around the aperture of the VCSEL. The aperture formed by the oxidation layer is referred to as an oxide aperture (OA).

Semiconductor lasers often use a circular or elliptical shaped oxide aperture to improve optical coupling efficiency, for example, with a fiber, and to provide more tolerance. A downside of circular apertures and other symmetrical apertures is that the linearly polarized (LP) modes have many degenerate modes. FIG. 1 shows the LP modes, including degenerate modes, produced in a circular waveguide having infinite rotation symmetry and line symmetry.

Aside from the degenerate modes, instability of polarization induces noise. Relative intensity noise (RIN) and mode partition noise (MPN) are both types of noise that may occur in a VCSEL device. MPN is caused by the instantaneous fluctuation of the power redistribution among the laser modes and differential delay of modes due to chromatic dispersion. The signal-to-noise ratio due to MPN is independent of signal power and error rate and thus cannot be reduced by increasing the received signal power.

FIG. 2A shows a schematic illustration of an elliptical oxide aperture 10 having a short radius (a) and a long radius (b), which may be used in a VCSEL. FIG. 2B is a graph of the relative intensity noise (RIN) versus normal quantiles for different ellipticities (i.e., different short and long radii) of the elliptical oxide aperture 10. As shown, using an elliptical oxide aperture having an ellipticity (e.g., ratio of short radius (a)/long radius (b)) between 0.6 and 0.8, may reduce RIN and improve the RIN yield as compared to a circular oxide aperture with an ellipticity of 1. One example of a VCSEL with an elliptical oxide aperture is disclosed in U.S. Pat. No. 10,305,254, which is incorporated herein by reference, and FIGS. 2A and 2B are reproduced from U.S. Pat. No. 10,305,254. A VCSEL with the elliptical oxide aperture, however, may not provide the desired oxide aperture (OA) tolerance and control limit needed for high-speed applications (e.g., 400 G/800 G).

Certain applications using a VCSEL (e.g., a 50 Gbit/s or 100 Gbit/s PAM-4 operation) also require a very small oxide aperture (OA<=7 μm) in the VCSEL. Oxide aperture control is also one limiting factor for device yield because, with reducing OA sizes, the variation of the oxide aperture results in a bigger variation of OA area, which affects device reliability and performance.

### SUMMARY

Consistent with an aspect of the present disclosure, a vertical cavity surface emitting laser (VCSEL) device includes an active region, an emission surface and an oxidation area located between the active region and the emission surface. The oxidation area defines an asymmetric oxide aperture with a low symmetry pattern having an order of rotation symmetry of zero.

Consistent with another aspect of the present disclosure, a method is provided for making a vertical cavity surface emitting laser (VCSEL) device. The method includes: depositing semiconductor layers on a substrate, wherein the semiconductor layers include an active region; etching at least one trench in the semiconductor layers around a region to form an oxidation area in at least one of the semiconductor layers, the at least one trench defines an asymmetric shape of the oxidation area; and oxidizing the at least one of the semiconductor layers via the at least one trench to form the oxidation area defining an asymmetric oxide aperture corresponding to the asymmetric shape defined by the at least one trench, wherein the asymmetric shape is a low symmetry pattern having an order of rotation symmetry of zero.

### BRIEF DESCRIPTION OF THE DRAWINGS

These and other features and advantages will be better understood by reading the following detailed description, taken together with the drawings wherein:

FIG. 1 is an image illustrating linearly polarized (LP) modes produced in a circular waveguide.

FIG. 2A is a schematic illustration of an elliptical oxide aperture used in a vertical cavity surface emitting laser (VCSEL).

FIG. 2B is a graph of the relative intensity noise (RIN) versus normal quantiles for different ellipticities of the oxide aperture in a VCSEL.

FIG. 3 is a cross-sectional view of a VCSEL device including an asymmetric oxide aperture, consistent with embodiments of the present disclosure.

FIGS. 4A and 4B are schematic diagrams illustrating circle and ellipse patterns having a non-zero order of rotation symmetry.

FIGS. 4C and 4D are schematic diagrams illustrating low symmetry patterns having an order of rotation symmetry of zero, which may be used for an asymmetric oxide aperture in a VCSEL device, consistent with embodiments of the present disclosure.

FIGS. 5A and 5B illustrate LP modes formed in a semi-circle waveguide and a triangle waveguide, respectively, consistent with embodiments of the present disclosure.

FIG. 6 is a schematic diagram illustrating examples of low symmetry partial circle patterns that may be used for an asymmetric oxide aperture in a VCSEL device to increase OA control limit, consistent with embodiments of the present disclosure.

FIG. 6A is a schematic diagram illustrating a half circle pattern that may be used for an asymmetric oxide aperture in a VCSEL device to increase OA control limit, consistent with an embodiment of the present disclosure.

FIG. 6B is a schematic diagram illustrating a quarter circle pattern that may be used for an asymmetric oxide aperture in a VCSEL device to increase OA control limit, consistent with an embodiment of the present disclosure.

FIG. 7 is a graph of OA yield v. OA control limit for circle and partial circle oxide apertures.

FIGS. 8A-8C illustrate an example of oxide aperture fabrication flow to produce a VCSEL device with an asymmetric oxide aperture, consistent with embodiments of the present disclosure.

FIG. 9A is a top view of a VCSEL device with a semi-circle oxide aperture, consistent with an embodiment of the present disclosure.

FIG. 9B is a top view of a VCSEL with a semi-circle oxide aperture and with a contact ring, consistent with another embodiment of the present disclosure.

### DETAILED DESCRIPTION

In a VCSEL device with an asymmetric oxide aperture, consistent with embodiments of the present disclosure, the asymmetric oxide aperture has a low symmetry shape or pattern with an order of rotation symmetry of zero. An oxide aperture having such a low symmetry pattern breaks the symmetry to eliminate degenerate modes and instability of polarization, which reduces relative intensity noise (RIN) and root-mean-square (RMS) spectra width. In one embodiment, the low symmetry pattern of the asymmetric oxide aperture may be a partial circle, such as a semi-circle or quarter circle, and the arc angle θ of the partial circle may be reduced to increase the OA control limit, as described in greater detail below.

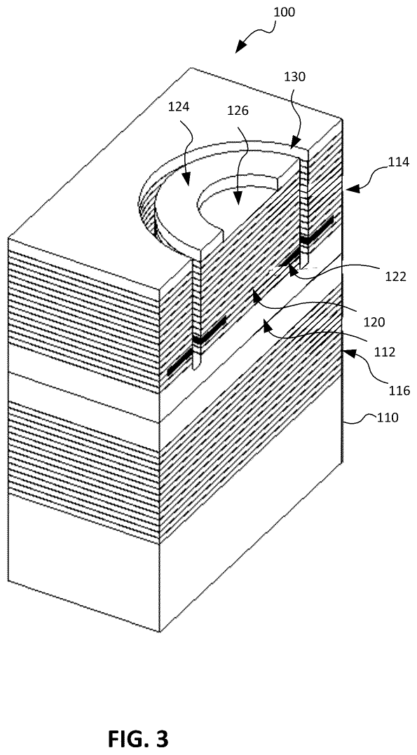

Referring to FIG. 3, an embodiment of a VCSEL device 100 including an asymmetric oxide aperture 120 having a low symmetry shape or pattern is described in greater detail. The VCSEL device 100 may include a substrate 110 with semiconductor layers formed thereon. The semiconductor layers may form, for example, an active region 112 (e.g., having one or more quantum wells) and upper and lower reflectors 114, 116 (e.g., distributed Bragg reflectors) above and below the active region 112. Other configurations for the VCSEL device 100 are also within the scope of the present disclosure.

In the VCSEL device 100, the asymmetric oxide aperture 120 is defined by an oxidation area 122 formed by one or more oxidized layers. The oxidation area 122 and the asymmetric oxide aperture 120 defined thereby are located between the active region 112 and a top emission surface 124 of the VCSEL device 100. The top emission surface 124 includes an emission aperture 126 for emitting laser light. The oxidation area 122 may be defined by one or more trenches 130 forming the desired low symmetry pattern, which forms the asymmetric oxide aperture 120 with a corresponding low symmetry pattern.

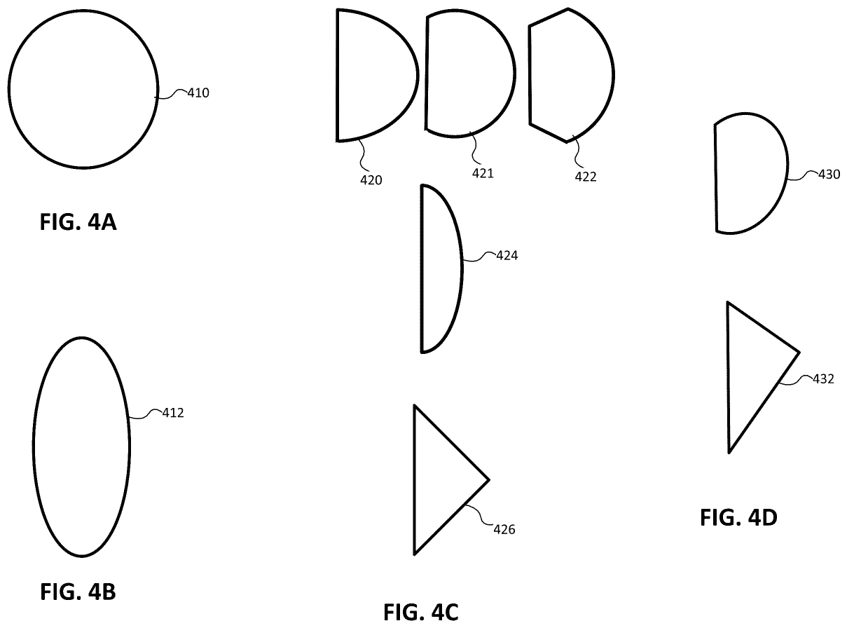

FIGS. 4A-4D show patterns that range from symmetric to asymmetric and illustrate the elimination of OA symmetry that can be achieved in a VCSEL device, consistent with embodiments of the present disclosure. FIGS. 4A and 4B show the symmetric patterns including a circle 410 (FIG. 4A) having an infinite order of rotation symmetry and line symmetry and an ellipse 412 (FIG. 4B) having an order of rotation symmetry of two (2) and a line symmetry of two (2). FIGS. 4C and 4D show examples of low symmetry patterns that may be used for the asymmetric oxide aperture in a VCSEL device (e.g., VCSEL device 100), consistent with embodiments of the present disclosure. An asymmetric oxide aperture generally has a low symmetry pattern with an order of rotation symmetry of zero. As shown in FIG. 4C, low symmetry patterns with an order of rotation symmetry of zero and a line symmetry of one (1) may include, without limitation, semi-circle shapes 420-422, a semi-ellipse shape 424, and a triangle shape 426. As shown in FIG. 4D, low symmetry patterns with an order of rotation symmetry of zero and a line symmetry of zero may include, without limitation, an arc shape 430 and a triangle shape 432. Thus, the low symmetry patterns used for the asymmetric oxide aperture in the VCSEL device, consistent with embodiments of the present disclosure, reduce or eliminate OA symmetry as compared to symmetric circle and ellipse patterns.

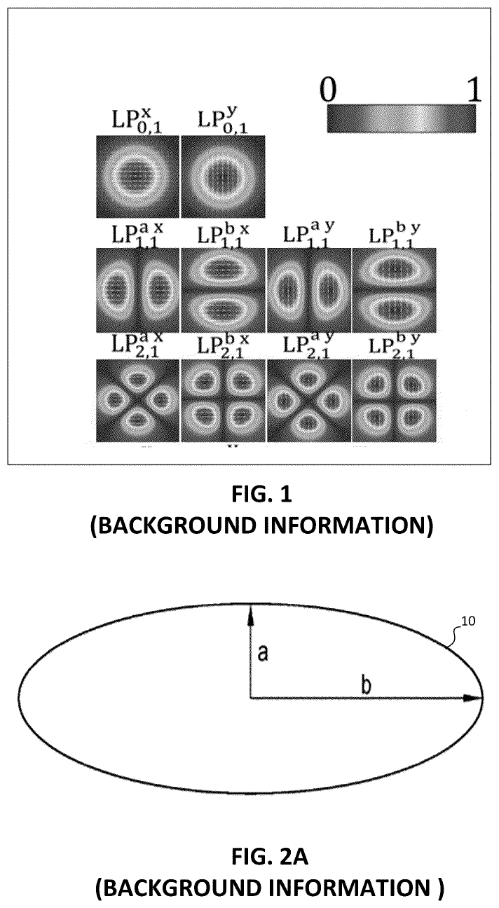

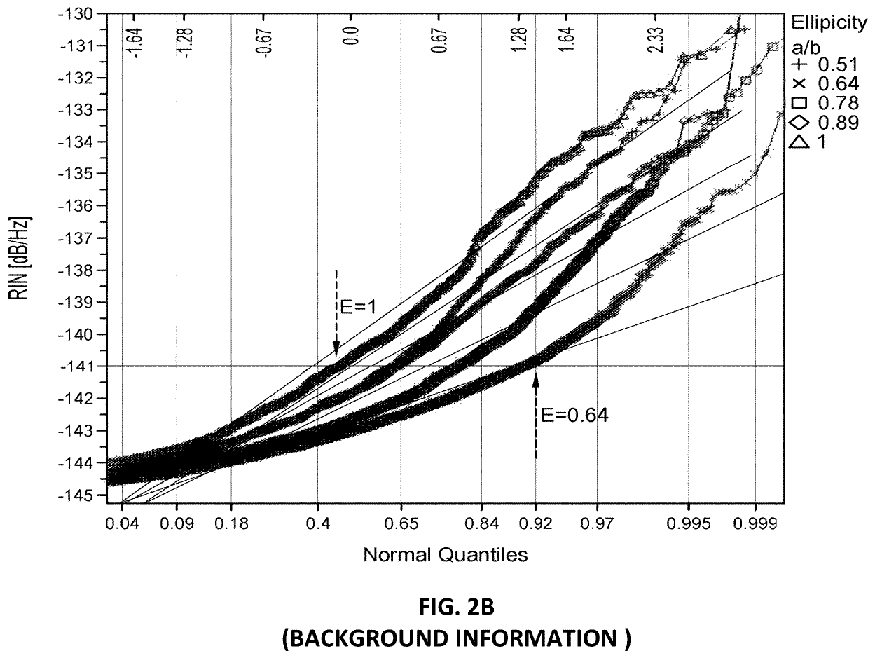

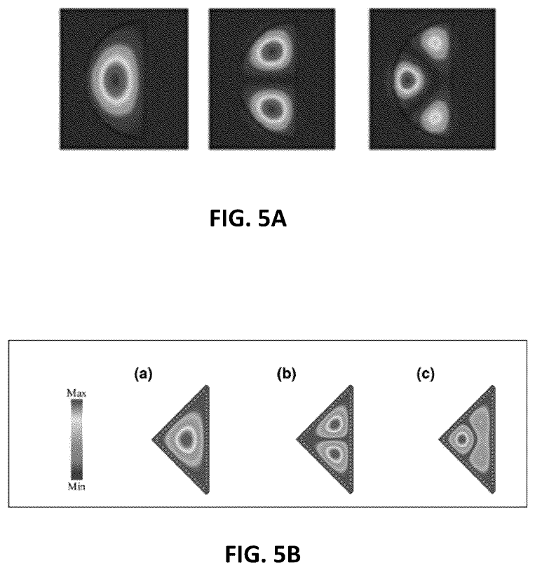

FIGS. 5A and 5B show the first three modes generated for a semi-circle waveguide and a triangle waveguide, respectively. As shown, breaking symmetry may eliminate degenerate modes that may be present with a symmetric ellipse or circle pattern (e.g., as shown in FIG. 1) and may eliminate instability of polarization. As a result, RIN and RMS spectra width may be reduced.

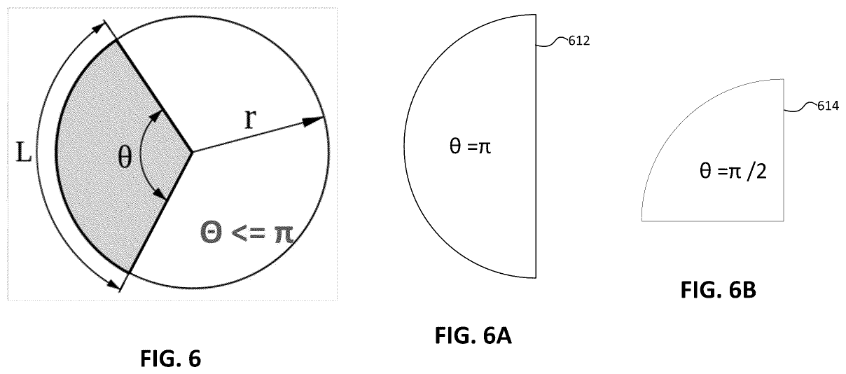

The asymmetric oxide aperture in a VCSEL device, consistent with embodiments of the present disclosure, may also increase the OA control limit. Referring to FIGS. 6, 6A and 6B, examples of partial circle patterns that may be used to increase the OA control limit are described in greater detail. As shown in FIG. 6, a partial circle pattern 600 may be defined as that portion of the circle having arc angle θ, where r is the radius and L is the arc length. An asymmetric oxide aperture may have a partial circle pattern with an arc angle θ≤π, such as a half circle OA 612 with an arc angle θ=π (FIG. 6A) and a quarter circle OA 614 with an arc angle Λ=π/2 (FIG. 6B).

To provide the same area as a circle OA, a partial circle OA with an arc angle θ≤π will have a larger radius r. In particular, for the same OA area, the radius of a partial circle OA is

$$\sqrt{\frac{2 π}{θ}}$$

times the radius of a circle OA. As a result, for the same change in OA area, the change in OA radius of the partial circle OA is

$$\sqrt{\frac{2 π}{θ}}$$

times the OA radius change of the circle OA. For example, the half circle OA 612 has a radius of \sqrt{2} time the radius of a circle OA having the same area, and for the same change in area, the change in radius of the half circle OA 612 is \sqrt{2} times the change in radius of the circle OA. A quarter circle OA 612 has a radius of 2 times the radius of a circle OA having the same area, and for the same change in area, the change in radius of the quarter circle OA 614 is 2 times the change in radius of the circle OA. For any arc angle θ, the OA control limit range is also

$$\sqrt{\frac{2 π}{θ}}$$

times the OA control limit range of a circle OA. Thus, the control limit range increases as the arc angle θ is reduced, which allows a wafer OA yield improvement.

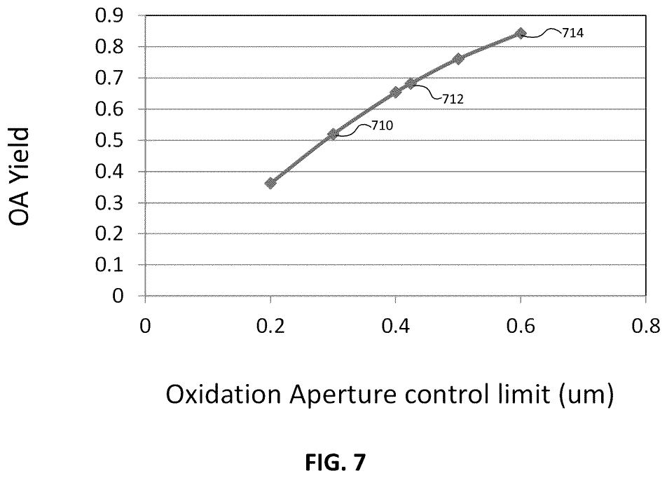

FIG. 7 illustrates an improvement in OA yield with an increase in the OA control limit based on a simulation. This simulation assumes an OA wafer to wafer uniformity standard deviation of 0.3 μm, an OA within wafer uniformity standard deviation of 0.3 μm, and an OA control limit of +/−0.3 μm. Taking a random 1000 points to simulate OA yield and plotting the circle OA yield 710, the semi-circle OA yield 712 and the quarter circle OA yield 714, the plot shows that OA yield increases 16% for a half circle OA and 22% for a quarter circle OA.

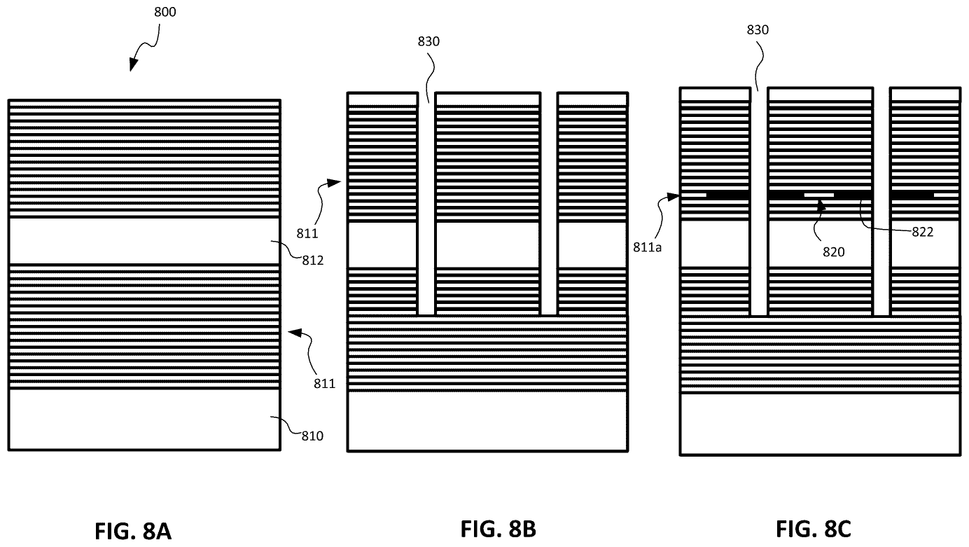

Referring to FIGS. 8A-8C, an oxidation aperture fabrication flow for producing a VCSEL device with an asymmetric oxide aperture, consistent with embodiments of the present disclosure, is described in greater detail. As shown in FIG. 8A, a VCSEL structure 800 may be formed by depositing semiconductor layers 811 on a substrate 810, for example, using techniques known to those of ordinary skill in the art such as chemical vapor deposition. The semiconductor layers 811 may include an active region 812.

As shown in FIG. 8B, one or more trenches 830 are etched in the semiconductor layers 811 around the region that will form the oxidation area and asymmetric oxide aperture. The one or more trenches 830 generally define the asymmetric shape or pattern of the oxide aperture but may have different layouts or configurations to define that shape or pattern. The trenches 830 may be etched using techniques known to those of ordinary skill in the art.

As shown in FIG. 8C, one or more of the semiconductor layers 811a may be oxidized using known oxidation techniques to form the oxidation area 822, which defines the asymmetric oxide aperture 820. The oxidation of the layer(s) 811a may be performed via the one or more trenches 830, for example, using water vapor as an oxidizing agent. Other methods and techniques may also be used to fabricate a VCSEL device with an asymmetric oxide aperture, consistent with the present disclosure.

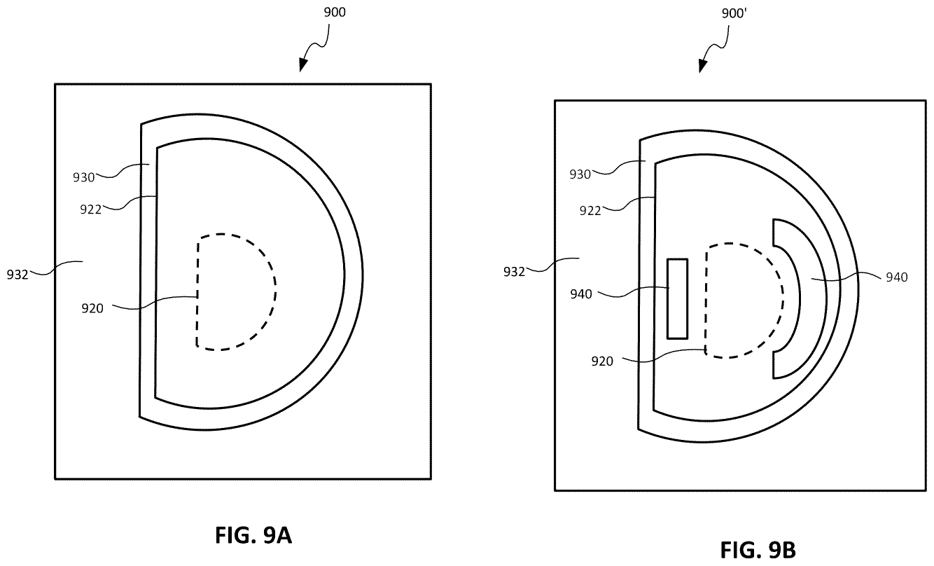

FIGS. 9 and 10 illustrate a top view of embodiments of a VCSEL device 900, 900′ showing the oxidation trench 930 being formed between an outside area 932 and an oxidation area 922, which defines an asymmetric oxide aperture 920. In this example, the oxidation area 922 and the asymmetric oxide aperture 920 defined thereby have a semi-circle low symmetry pattern. As shown, forming the one or more trenches 930 with the low symmetry pattern results in the oxidation area 922 defining the asymmetric oxide aperture 920 with a corresponding low symmetry pattern. As shown in FIG. 10, another embodiment of the VCSEL device 900′ includes electrical contacts 940 formed on the top and designed to adjust carrier distribution and gain distribution to minimize mode overlap and cross correlation, which may further reduce MPN.

Accordingly, a VCSEL device with an asymmetric oxide aperture having a low symmetry pattern, consistent with embodiments of the present disclosure, improves RIN and RMS spectrum width and increases OA process tolerance with significant wafer oxide aperture yield improvements.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. A vertical cavity surface emitting laser (VCSEL) device comprising:
an active region;
an emission surface; and
an oxidation area located between the active region and the emission surface, the oxidation area defining an asymmetric oxide aperture with a low symmetry pattern having an order of rotation symmetry of zero.

2. The VCSEL device of claim 1, wherein the asymmetric oxide aperture has a line symmetry of one.

3. The VCSEL device of claim 1, wherein the asymmetric oxide aperture has a line symmetry of zero.

4. The VCSEL device of claim 1, wherein the asymmetric oxide aperture has a shape selected from the group consisting of a semi-circle, a semi-ellipse, a triangle and an arc.

5. The VCSEL device of claim 1, wherein the asymmetric oxide aperture has a partial circle shape with an arc defined by an arc angle of θ≤π.

6. The VCSEL device of claim 1, wherein the asymmetric oxide aperture has a partial circle shape with an arc defined by an arc angle of θ≤π/2.

7. The VCSEL device of claim 1, wherein the asymmetric oxide aperture has a half circle shape.

8. The VCSEL device of claim 1, wherein the asymmetric oxide aperture has a quarter circle shape.

9. The VCSEL device of claim 1, further comprising at least one oxidation trench around at least a portion of the oxidation area.

10. The VCSEL device of claim 1, further comprising an upper reflector above the active region and a lower reflector below the active region.

11. The VCSEL device of claim 10, wherein the upper reflector and the lower reflector are distributed Bragg reflectors.

12. The VCSEL device of claim 1, wherein the emission surface defines an emission aperture.

13. The VCSEL device of claim 1, further comprising a contact on the emission surface.

14. A method of making a vertical cavity surface emitting laser (VCSEL) device, comprising:
depositing semiconductor layers on a substrate, wherein the semiconductor layers include an active region;
etching at least one trench in the semiconductor layers around a region to form an oxidation area in at least one of the semiconductor layers, the at least one trench defines an asymmetric shape of the oxidation area; and
oxidizing the at least one of the semiconductor layers via the at least one trench to form the oxidation area defining an asymmetric oxide aperture corresponding to the asymmetric shape defined by the at least one trench, wherein the asymmetric shape is a low symmetry pattern having an order of rotation symmetry of zero.

15. The method of claim 14, wherein the asymmetric oxide aperture has a line symmetry of one.

16. The method of claim 14, wherein the asymmetric oxide aperture has a line symmetry of zero.

17. The method of claim 14, wherein the asymmetric oxide aperture has a partial circle shape with an arc defined by an arc angle of θ≤π.

18. The method of claim 14, wherein the asymmetric oxide aperture has a quarter circle shape.

19. The method of claim 14, further comprising providing electrical contacts on a top of the VCSEL device.
